(19) United States
(12) Patent Application Publication
(10) Pub. No.: US 2013/0069501 A1
(43) Pub. Date: Mar. 21, 2013

(54) COMBINED FRAME FOR AN ELECTROMECHANICAL BOX

(71) Applicant: Keng-Fu LIU, Changhua City (TW)

(72) Inventor: Keng-Fu LIU, Changhua City (TW)

(73) Assignee: TAIWAN ENCLOSURE SYSTEMS CO., LTD., Kaohsiung City (TW)

(21) Appl. No.: 13/541,451

(22) Filed: Jul. 3, 2012

(30) Foreign Application Priority Data
Sep. 15, 2011 (TW) 100217270

(51) Int. Cl. H05K 7/18

(52) U.S. Cl. 312/223.1

(57) ABSTRACT

A combined frame for an electromechanical box has eight transversal beams, eight major connectors and four longitudinal columns. Each transversal beam has a body, two side covers and two fasteners. The side covers are securely mounted on the body and each has a fastening hole. The fasteners are respectively connected to the fastening holes of the side covers. Each major connector is connected to two adjacent transversal beams and has an internal surface, an external surface, a bottom, a top, an abutting wall, two through holes and a mounting hole. The longitudinal columns are connected to the major connectors between the transversal beams and each longitudinal column has a body, two minor connectors and two fixing elements. The minor connectors are respectively and securely mounted in the body and are respectively connected to the major connectors.

### BACKGROUND OF THE INVENTION

1. Field of the Invention

The present invention relates to a combined frame, and more particularly to a combined frame for an electromechanical box that can be assembled and positioned easily, can be assembled and carried conveniently to reduce the cost of transportation.

2. Description of Related Art

A conventional frame for an electromechanical box is assembled by multiple beams, multiple columns and multiple corner connectors. After assembling the beams, the columns and the corner connectors of the conventional frame, the beams, the columns and the corner connectors are connected to each other by welding. When the conventional frame is manufactured, the assemblement between the beams, the columns and the corner connectors is difficult and needs to be done in the manufacturing factory. The large space of the conventional frame will increase the costs for transporting the conventional frame.

Furthermore, a conventional combined frame is assembled by multiple modular connectors, multiple beams and multiple columns. The modular connectors are used to the replace the corner connectors of the conventional frame to solve the problem of difficult assemblement of the corner connectors. However, the beams, the columns and the modular connectors are securely connected to each other by welding after assembling, the fixed structure of the conventional combined frame can not be detached and the large space that the conventional combined frame occupies will increase the costs for transporting the conventional combined frame.

The combined frame for an electromechanical box in accordance with the present invention mitigates or obviates the aforementioned problems.

### SUMMARY OF THE INVENTION

The main objective of the present invention is to provide a combined frame for an electromechanical box that can be assembled and positioned easily, can be assembled without welding and carried conveniently to reduce the cost of transportation.

The combined frame for an electromechanical box in accordance with the present invention has eight transversal beams, eight major connectors and four longitudinal columns. Each transversal beam has a body, two side covers and two fasteners. The side covers are securely mounted on the body and each has a fastening hole. The fasteners are respectively connected to the fastening holes of the side covers. Each major connector is connected to two adjacent transversal beams and has an internal surface, an external surface, a bottom, a top, an abutting wall, two through holes and a mounting hole. The longitudinal columns are connected to the major connectors between the transversal beams and each longitudinal column has a body, two minor connectors and two fixing elements. The minor connectors are respectively and securely mounted in the body and are respectively connected to the major connectors. The fixing elements are mounted through the minor connectors and are securely mounted in the corresponding major connectors to connect the longitudinal column securely with the corresponding major connectors.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of a first embodiment of a combined frame for an electromechanical box in accordance with the present invention;

FIG. 2 is an enlarged perspective view of a mounting frame of the combined frame in FIG. 1;

FIG. 3 is an enlarged and exploded perspective view of the mounting frame of the combined frame in FIG. 2;

FIG. 4A is an enlarged perspective view of a transversal beam of the combined frame in FIG. 1;

FIG. 4B is an enlarged perspective view of the transversal beam of the combined frame in FIG. 4A;

FIG. 5 is an enlarged perspective view of a major connector of the combined frame in FIG. 1;

FIG. 6 is another enlarged perspective view of a major connector of the combined frame in FIG. 1;

FIG. 7 is an enlarged perspective view of a longitudinal column of the combined frame in FIG. 1;

FIG. 8 is an enlarged and exploded perspective view of the combined frame in FIG. 1;

FIG. 9 is another enlarged and exploded perspective view of the combined frame in FIG. 1;

FIG. 10 is a perspective view of a second embodiment of a combined frame for an electromechanical box in accordance with the present invention;

FIG. 11 is an enlarged and exploded perspective view of the combined frame in FIG. 10;

FIG. 12 is a perspective view of a third embodiment of a combined frame for an electromechanical box in accordance with the present invention;

FIG. 13 is an enlarged perspective view of a longitudinal column of the combined frame in FIG. 12; and

FIG. 14 is an exploded and enlarged perspective view of a linking set of the longitudinal column in FIG. 13.

### DETAILED DESCRIPTION OF PREFERRED EMBODIMENT

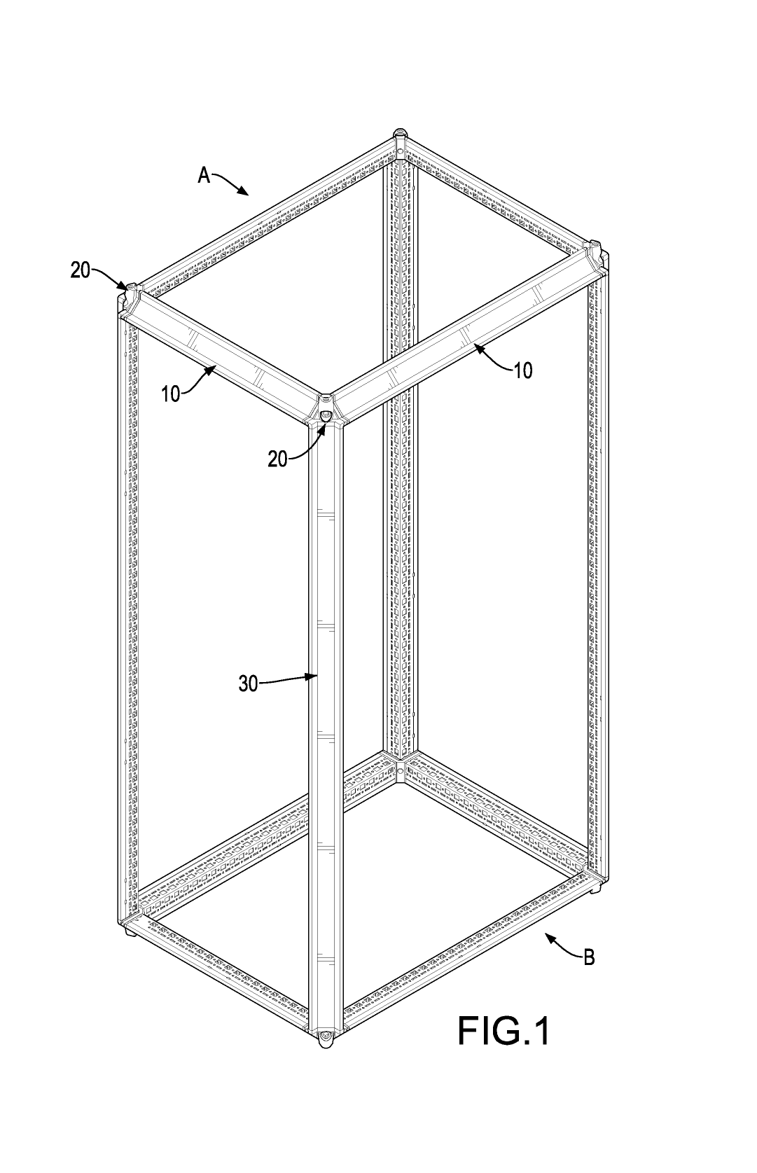

With reference to FIG. 1, a combined frame in accordance with the present invention for an electromechanical box comprises eight transversal beams 10, eight major connectors 20 and four longitudinal columns 30.

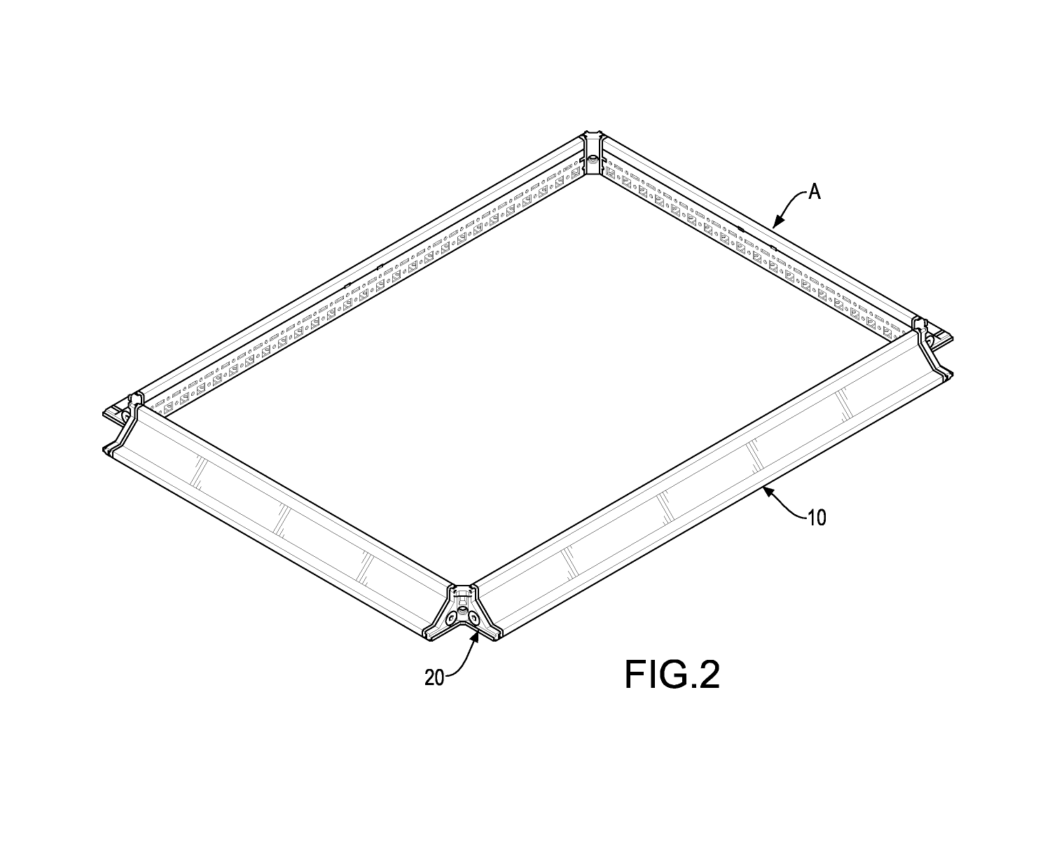

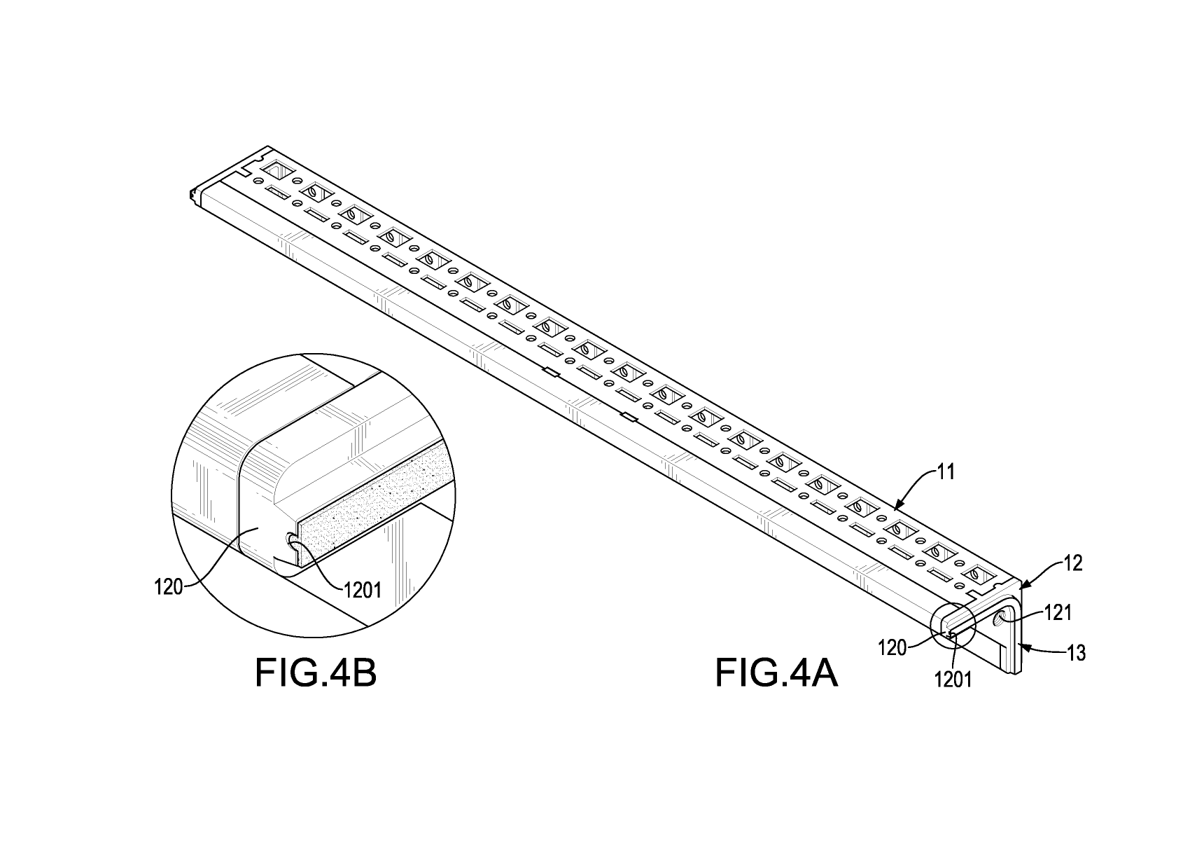

With reference to FIGS. 2, 3, 4A and 4B, each transversal beam 10 has a body 11, two side covers 12, two waterproof bars 13 and two fasteners 14. The body 11 is L-shaped in cross section and has an external surface, two ends, multiple holding holes and two mounting holes. The holding holes are formed in the external surface of the body 11 at intervals between the ends of the body 11. The mounting holes are respectively formed through the ends of the body 11.

The side covers 12 are L-shaped, are respectively and securely mounted in the mounting holes of the body 11, and each side cover 12 has an inner side, an outer side, a middle, a positioning bar 120 and a fastening hole 121. The inner side of the side cover 12 abuts a corresponding end of the body 11. The positioning bar 120 may be L-shaped, is formed on and protrudes from the outer side of the side cover 12 and has an external surface and an engaging slot 1201. The engaging slot 1201 is formed in the external surface of the positioning bar 120. The fastening hole 121 is formed in the middle of the side cover 12.

The waterproof bars 13 are respectively mounted on and abut the external surfaces of the positioning bars 120 of the side covers 12 and respectively engage the engaging slots 1201 of the positioning bars 120. The fasteners 14 are respectively connected to the fastening holes 121 of the side covers 12.

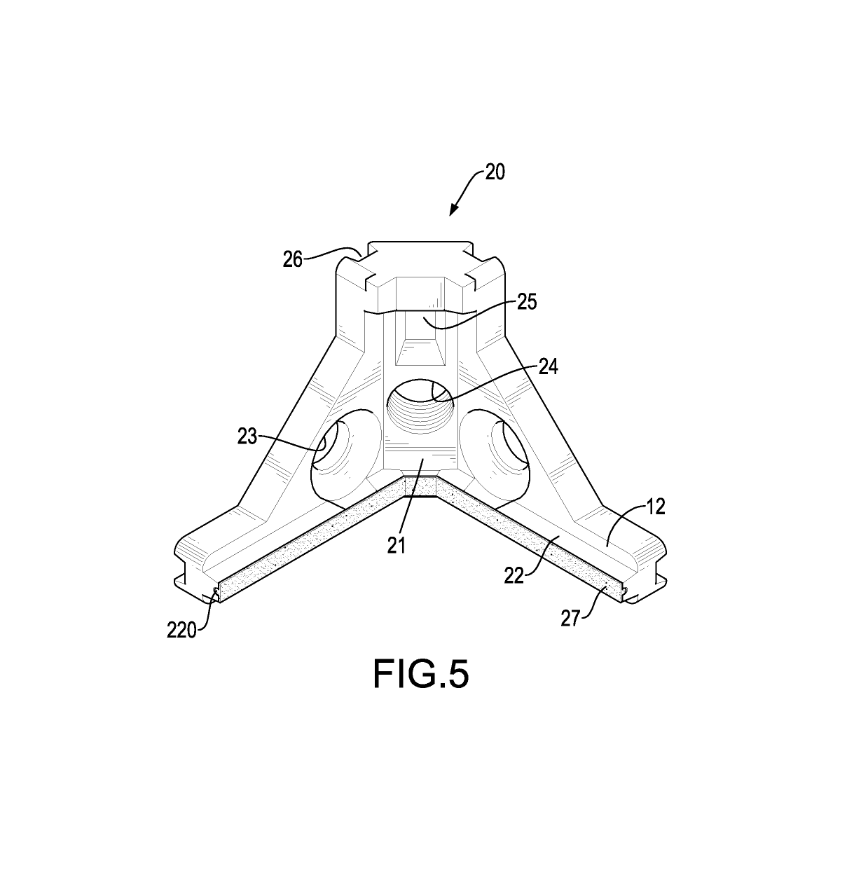

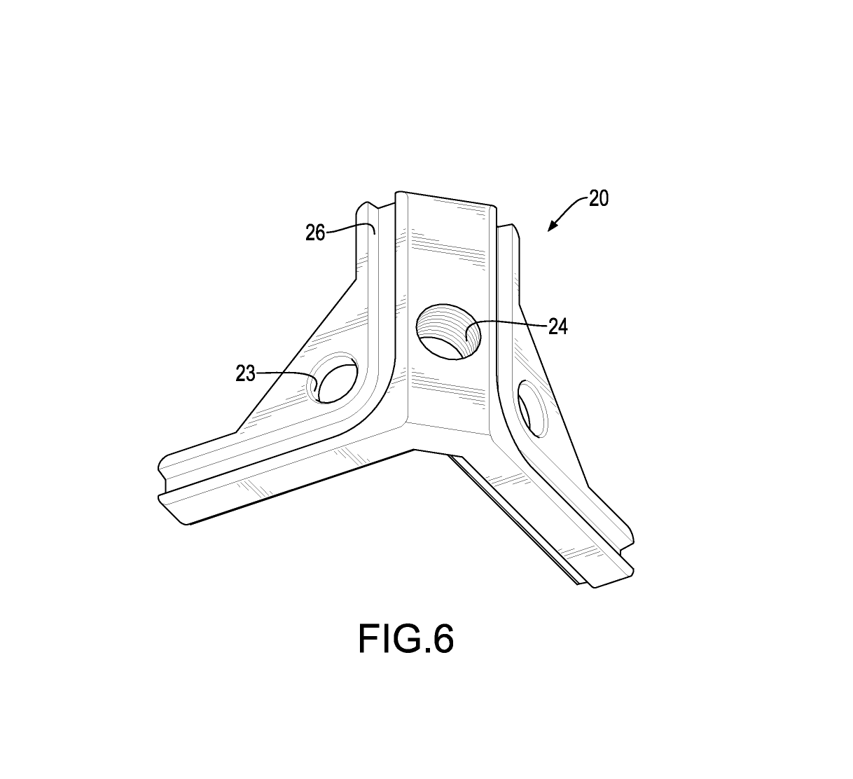

With reference to FIGS. 5 and 6, each major connector 20 may be L-shaped, is connected to two adjacent transversal beams 10 and has an internal surface, an external surface, a bottom, a top, an abutting wall 21, a positioning arm 22, two through holes 23, a mounting hole 24, a positioning recess 25, two positioning slots 26 and a waterproof bar 27. The internal surface of the major connector 20 has a middle face and two side faces. The side faces are formed with the middle face. The external surface of the major connector 20 has two side faces respectively parallel the side faces of the internal surface of the major connector 20.

The abutting wall 21 is defined on the middle face of the internal surface of the major connector 20 between the side faces of the internal surface of the major connector 20. The positioning arm 22 is formed on and protrudes from the bottom of the major connector 20 along the internal surface and has an inner face and a mounting slot 220. The mounting slot 220 is formed in the inner face of the positioning arm 22.

The through holes 23 are respectively formed through the side faces of the internal surface and the external surface of the major connector 20 above the positioning arm 22 and respectively align with two of the fastening holes 121 of the adjacent transversal beams 10. The mounting hole 24 is formed through the abutting wall 21 and the external surface of the major connector 20. The positioning recess 25 is formed in the abutting wall 21 between the mounting hole 24 and the top of the major connector 20.

The positioning slots 26 are respectively formed in the side faces of the external surface of the major connector 20 from the top to the positioning arm 22 of the major connector 20 and have shapes corresponding to the positioning bars 120 of the adjacent transversal beams 10. The waterproof bar 27 is mounted on and abuts the inner face of the positioning arm 22 and engages the mounting slot 220 of the positioning arm 22.

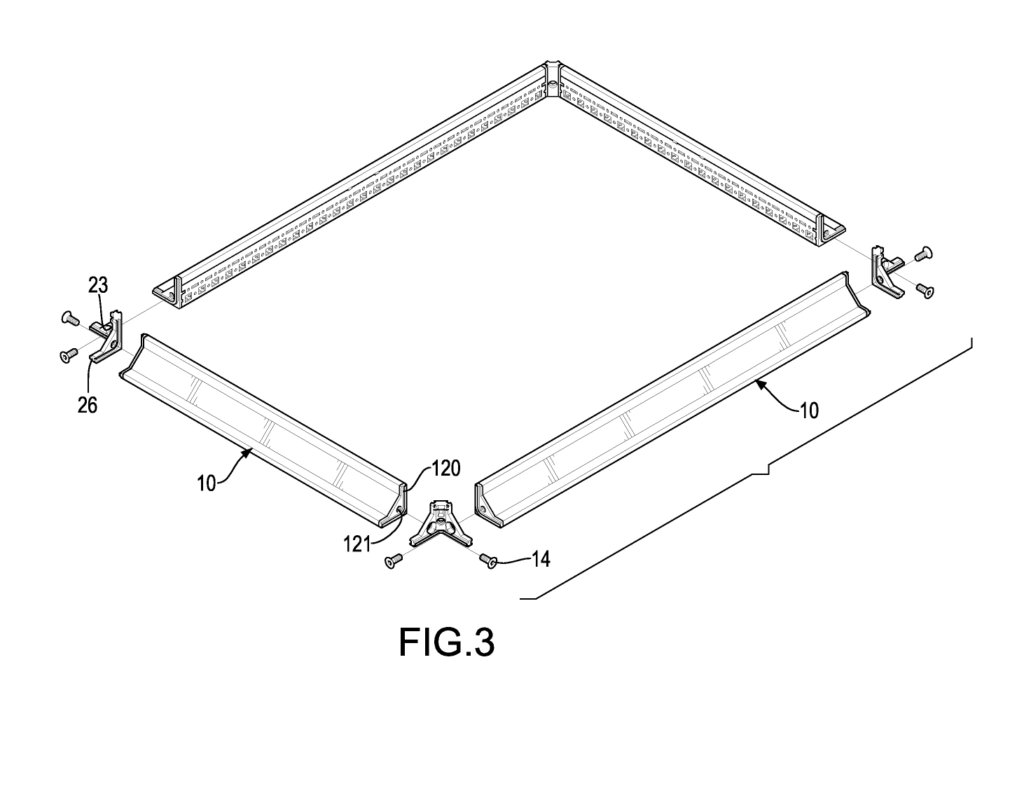

With reference to FIGS. 2 and 3, four of the adjacent transversal beams 10 are connected to four of the major connectors 20 by the positioning slots 26 of the corresponding major connectors 20 respectively engaging the positioning bars 120 of the corresponding adjacent transversal beams 10 to enable the fastening holes 121 of the corresponding transversal beams 10 to respectively align the through holes 23 of the corresponding major connectors 20. Then, the fasteners 14 are respectively connected to the fastening holes 121 of the corresponding transversal beams 10 via the corresponding through holes 23 of the corresponding major connectors 20 to connect the corresponding transversal beams 10 with each other by the corresponding major connectors 20 to form a rectangular mounting frame A, B. By the same means of assembling the other transversal beams 10 and the other major connectors 20 to form another mounting frame A, B. With reference to FIG. 1, the two mounting frames A, B that are formed by the transversal beams 10 and the major connectors 20 are respectively defined as a top mounting frame A and a bottom mounting frame B.

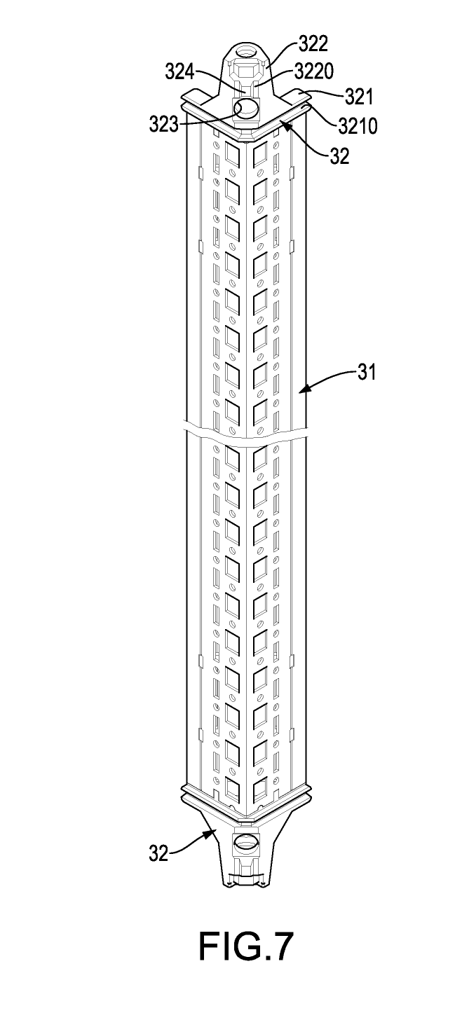

With reference to FIGS. 7, 8 and 9, the longitudinal columns 30 are connected to the major connectors 20 between the mounting frames A, B, and each longitudinal column 30 has a body 31, two minor connectors 32 and two fixing elements 33. The body 31 is a L-shaped in cross section and has an external surface, two ends, multiple holding holes and two mounting holes. The holding holes are formed in the external surface of the body 31 at intervals between the ends of the body 31. The mounting holes are respectively formed through the ends of the body 31.

The minor connectors 32 are respectively and securely mounted in the mounting holes of the body 31 and are respectively connected to two of the major connectors 20, and each minor connector 32 has a locating segment 321, a mounting stud 322, an assembling hole 323 and a locating protrusion 324. The locating segment 321 is mounted in one of the mounting holes of the body 31 and has a shape, a bottom, a top, a middle, an external surface and a locating recess 3210. The shape of the minor locating segment 321 is corresponding to the shape of the mounting holes of the body 31. The locating recess 321 is formed in the external surface of the locating segment 321 at the bottom of the locating segment 321 and engages the positioning arm 22 of a corresponding major connector 20.

The mounting stud 322 may be semicircular in cross section, is formed on and protrudes from the top of the locating segment 321 at the middle of the locating segment 321 and abuts the internal surface of the major connector 20. The mounting stud 322 has an external surface and a pressing wall 3220. The pressing wall 3220 is formed on the external surface of the mounting stud 322 and faces and abuts the abutting wall 21 of the corresponding major connector 20. The assembling hole 323 is transversally formed through the mounting stud 322 between the pressing wall 3220 and the locating segment 321 and aligns with the mounting hole 24 of the corresponding major connector 20. The locating protrusion 324 is formed on and protrudes from the pressing wall 3220 of the mounting stud 322 above the assembling hole 323 and is mounted in the positioning recess 25 of the corresponding major connector 20.

The fixing elements 33 are mounted through the assembling holes 323 of the minor connectors 32 and are securely mounted in the mounting holes 24 of the corresponding major connectors 20 to connect the longitudinal column 30 securely with the corresponding major connectors 20.

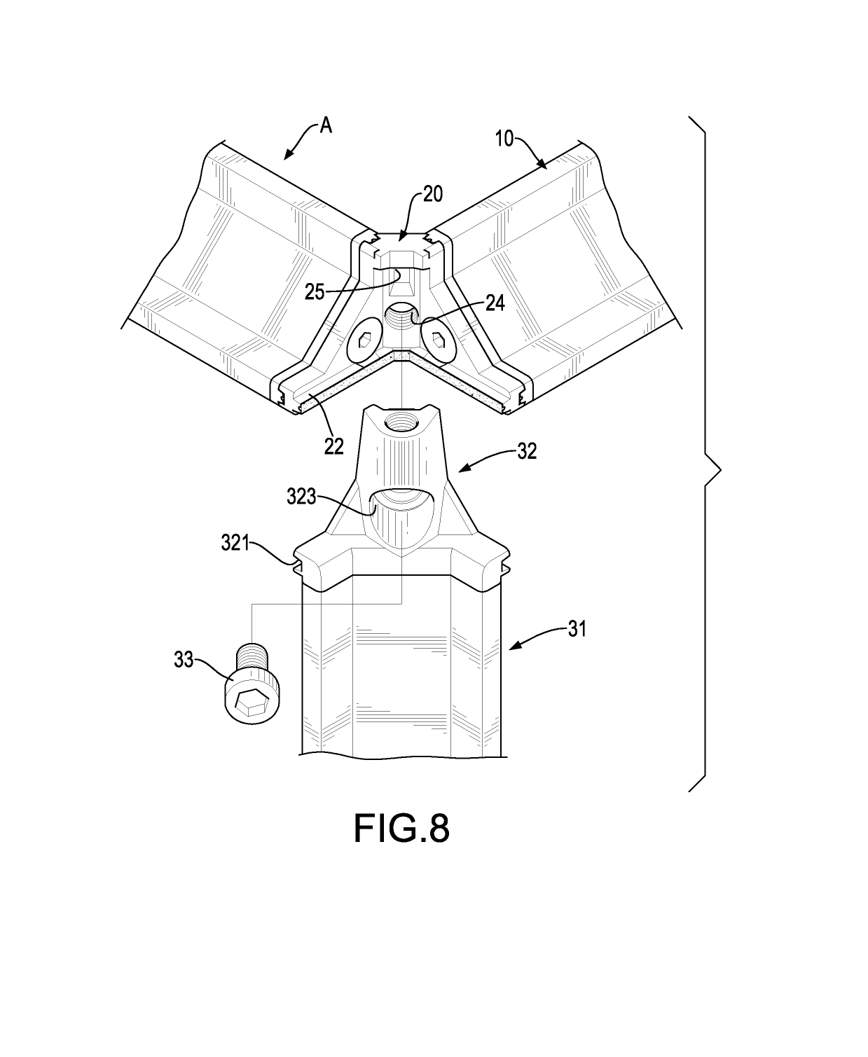

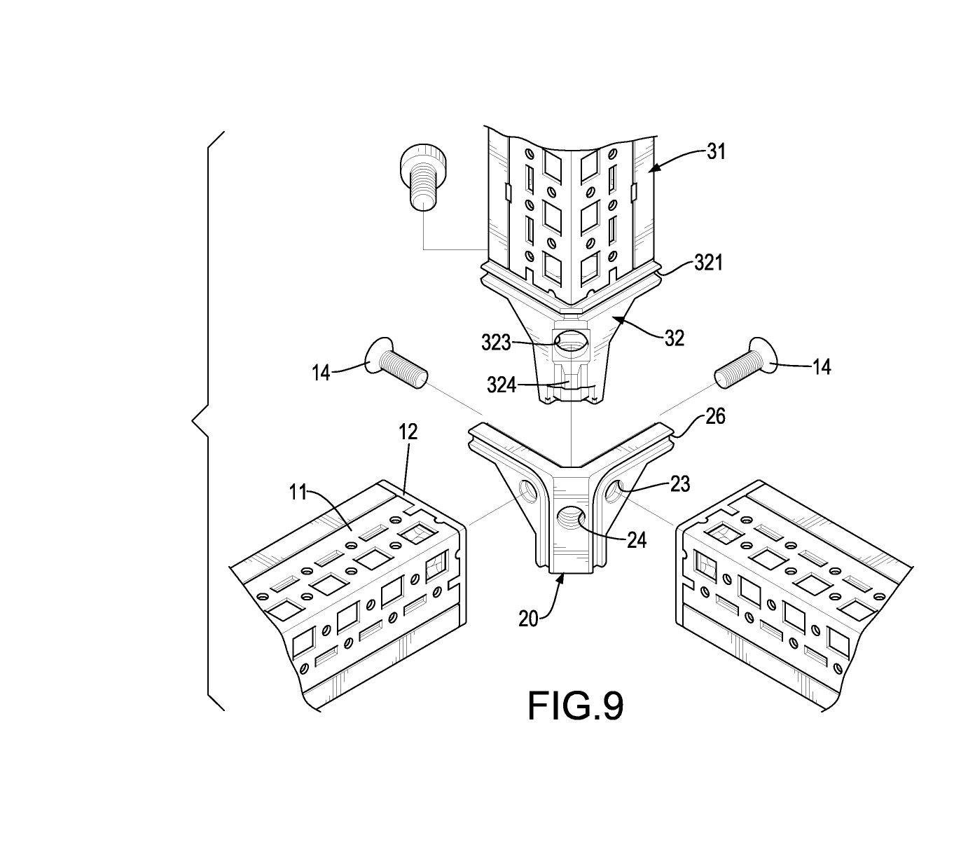

With reference to FIGS. 8 and 9, the longitudinal columns 30 are securely connected to the mounting frames A, B by the fixing elements 33 mounting through the assembling holes 323 of the minor connectors 32 and securely mounting in the mounting holes 24 of the major connectors 20 to form the combined frame in accordance with the present invention shown in FIG. 1.

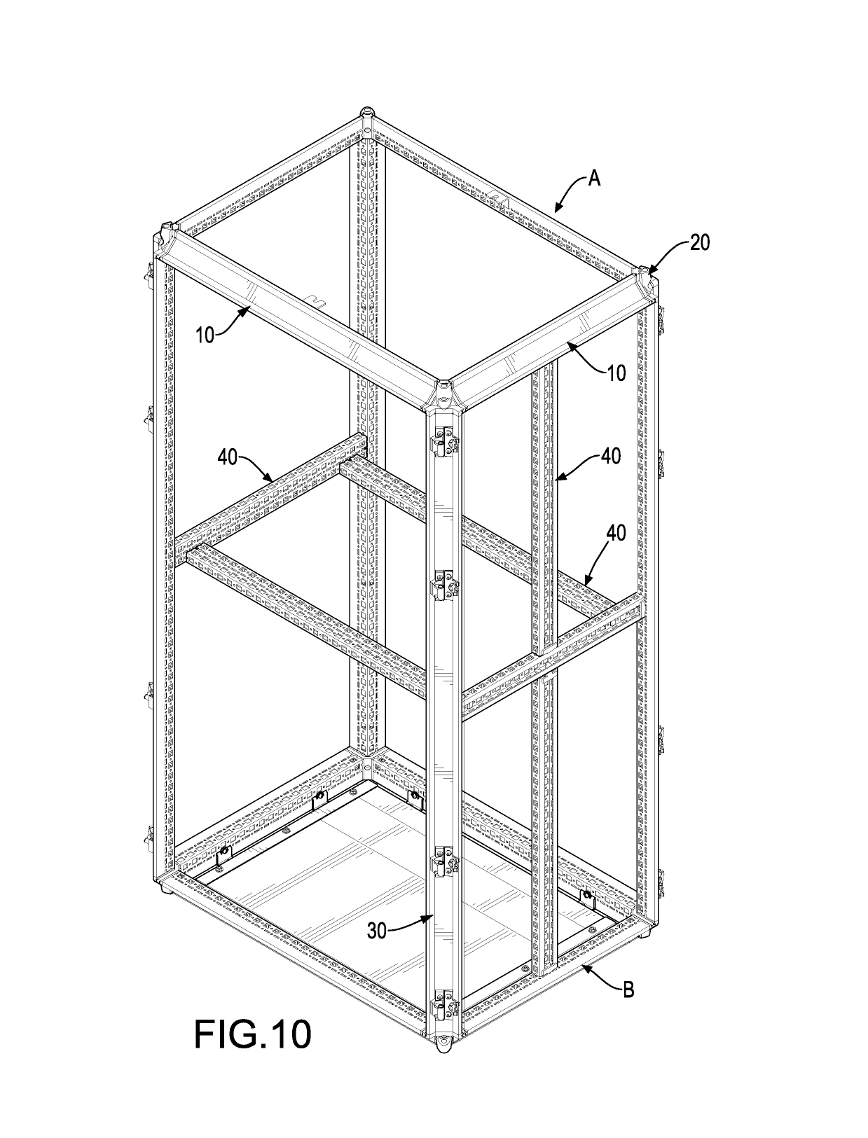

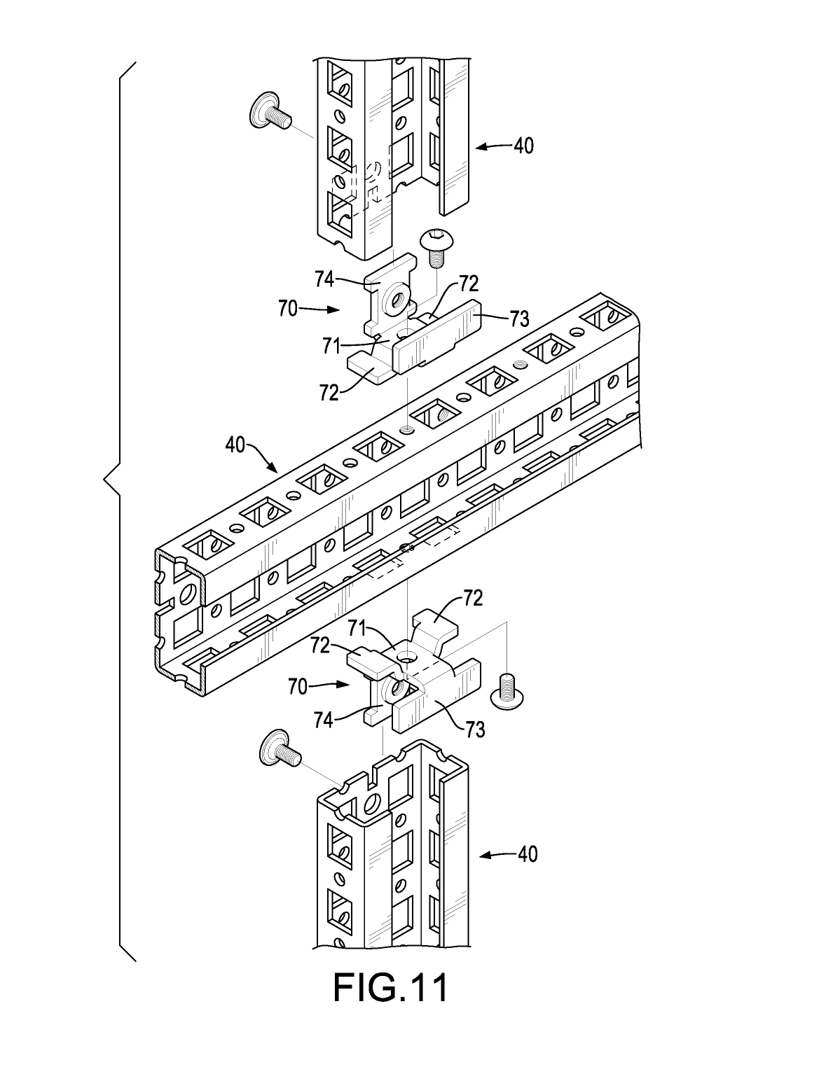

With further reference to FIGS. 1 and 2, in assembling, the mounting frames A, B that are formed by the transversal beams 10 and the major connectors 20 can be used as the top and the bottom of the combined frame in accordance with the present invention, and the longitudinal columns 30 are respectively and securely connected to the major connectors 20 between the mounting frames A, B by the fixing elements 33 to form the combined frame without welding. Therefore, the combined frame in accordance with the present can be assembled or disassembled easily, and can be transported and then be connected to each other to form the combined frame quickly and easily. Then, the combined frame can be transported conveniently and the costs for transporting the combined frame can be reduced. In addition, the waterproof bars 13, 27 are mounted between the assemblement of the transversal beams 10, the major connectors 20 and the longitudinal columns 30 to provide a waterproof effect to the combined frame in accordance with the present invention. With reference to FIGS. 10 and 11, a second embodiment of a combined frame for an electromechanical box in accordance with the present invention has the similar structures as the first embodiment of a combined frame for an electromechanical box. In addition, the combined frame further has multiple supporting beams 40 connected between two adjacent longitudinal columns 30 or two transversal beams 10 of the mounting frames A, B to provide a preferred positioning effect to the combined frame to prevent the combined frame from deforming. In addition, the combined frame further has multiple assembling blocks 70 are connected between two adjacent supporting beams 40, and each assembling block 70 has a block body 71, two holding wings 72, a limiting panel 73 and a fastening board 74. The block body 71 is securely connected to one of the two adjacent supporting beams 40 and has two sidewalls, a front side and a rear side. The holding wings 72 are respectively formed with the sidewalls of the block body 71 and abut the supporting beam 40 that is securely connected to the block body 71. The limiting panel 73 is formed on and protrudes from the front side of the block body 71 and abuts with the other one of the two adjacent supporting beams 40. The fastening board 74 is formed on and protrudes from the rear side of the block body 71 and is securely connected to the supporting beam 40 that abuts with the limiting panel 73. Then, the two adjacent supporting beams 40 can be connected to each other by the assembling block 70.

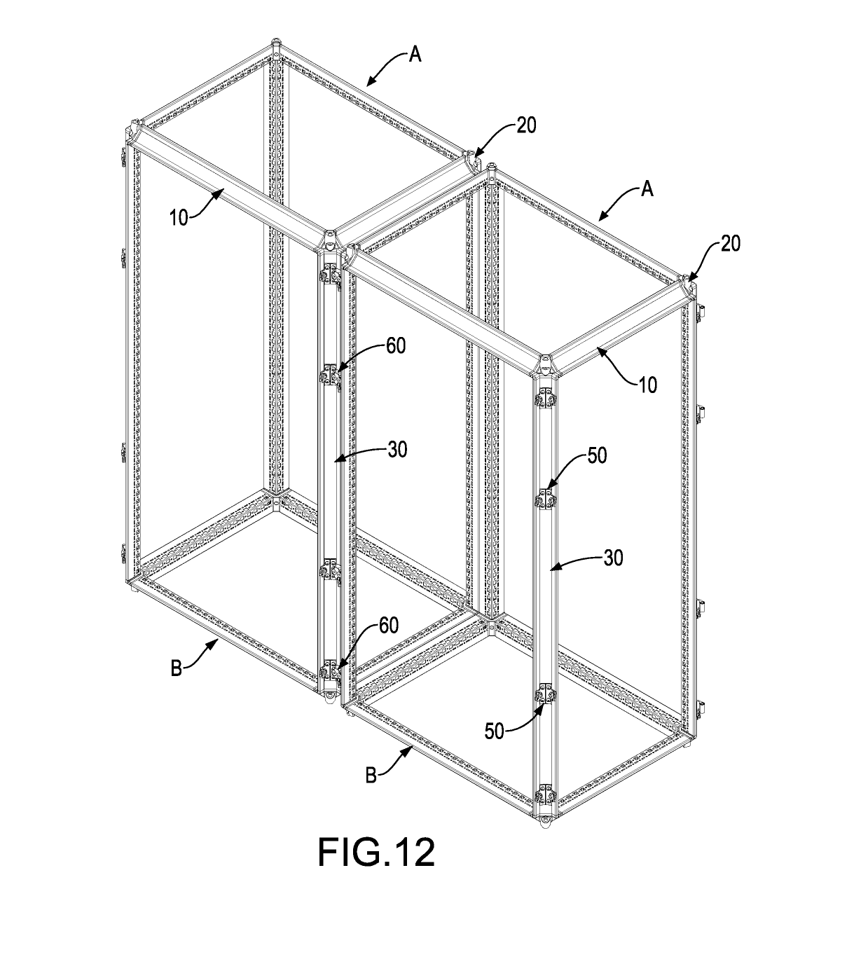

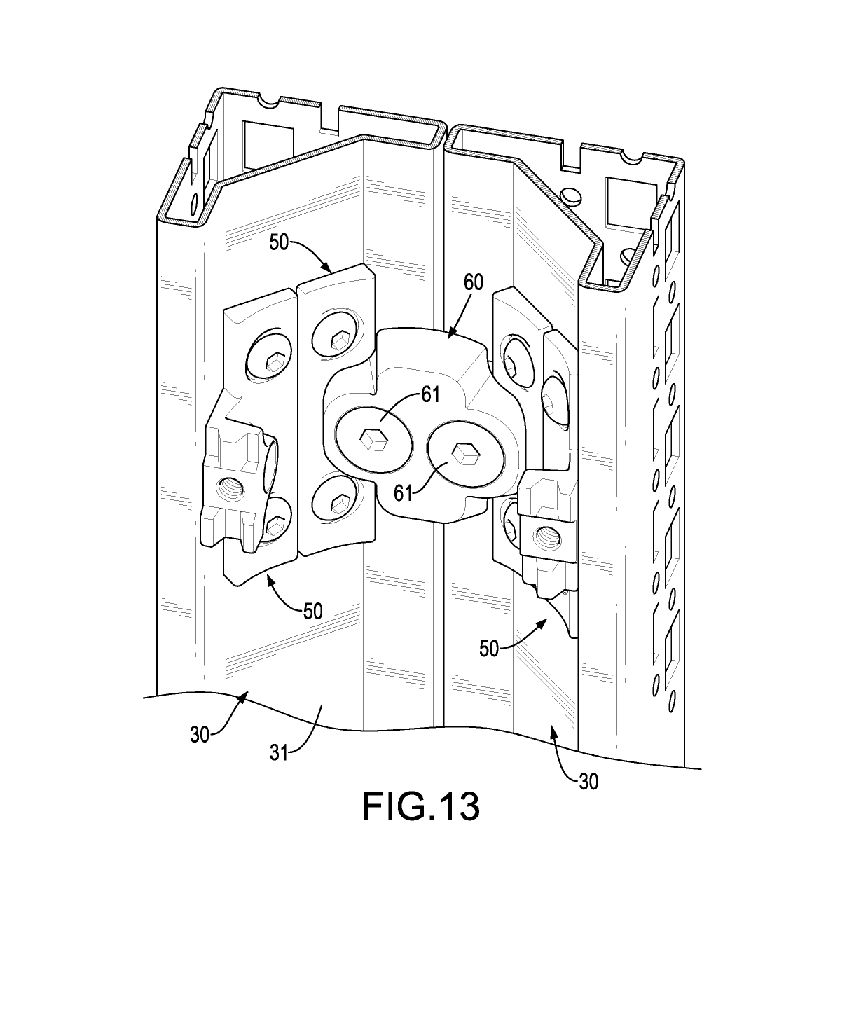

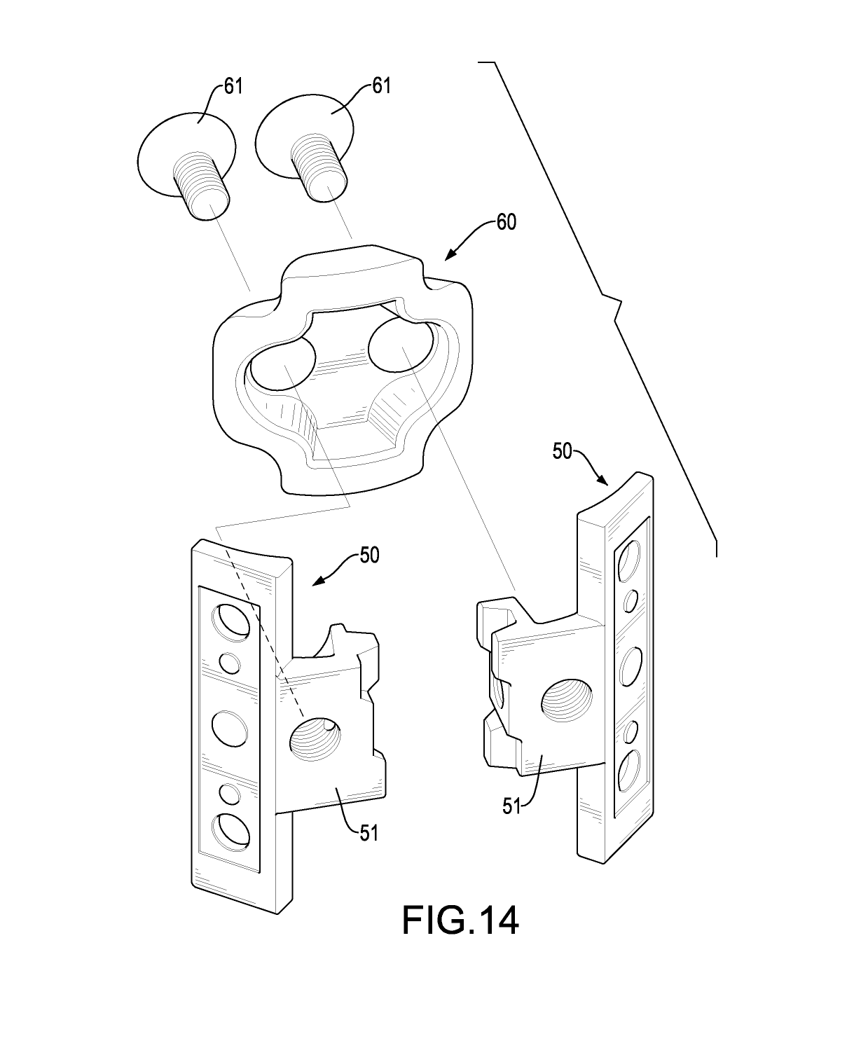

Additionally, with reference to FIGS. 12 to 14, the third embodiment of a combined frame for electromechanical box in accordance with the present invention has the similar structures as the first embodiment of a combined frame for an electromechanical box. In addition, each one of the longitudinal columns 30 further has multiple linking sets mounted on the body 31 of the corresponding longitudinal column 30 at intervals to connect a longitudinal column 30 of an adjacent combined frame. Each linking set has two linking blocks 50 and a connecting base 60. Each linking block 50 is detachably mounted on the body 31 of a corresponding longitudinal column 30 by fasteners and has a connecting tab 51 formed on and protrudes from an outer side of the block 50. The connecting tab 51 of the linking block 50 of the longitudinal column 30 of the combined frame is connected to the connecting tab 51 of the linking block 50 of a longitudinal column 30 of an adjacent combined frame. The connecting base 60 is mounted around the connecting tabs 51 of the corresponding linking blocks 50 of the two adjacent combined frames and has two bolts 61 respectively and securely screwed to the connecting tabs 51 of the corresponding linking blocks 50 to connect the longitudinal columns 30 of the two adjacent combined frames with each other.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A combined frame for an electromechanical box having
eight transversal beams, and each transversal beam having
a body having two ends;
two side covers respectively and securely mounted on the ends of the body, and each side cover having
an inner side abutting a corresponding end of the body;
an outer side;
a middle; and
a fastening hole formed in the middle of the side cover; and
two fasteners respectively connected to the fastening holes of the side covers;
eight major connectors, and each major connector connected to adjacent two of the transversal beams and having
an internal surface having
a middle face; and
two side faces formed with the middle face;
an external surface having two side faces respectively parallel the side faces of the internal surface of the major connector;
a bottom;
a top;
an abutting wall defined on the middle face of the internal surface of the major connector between the side faces of the internal surface of the major connector;
two through holes respectively formed through the side faces of the internal surface and the external surface of the major connector and respectively aligning with two of the fastening holes of the adjacent transversal beams to enable the corresponding fasteners to mount through the through holes and to mounted in the corresponding fastening holes; and
a mounting hole formed through the abutting wall and the external surface of the major connector above the through holes; and
four longitudinal columns connected to the major connectors between the transversal beams, and each longitudinal column having
a body having two ends;
two minor connectors respectively and securely mounted on the ends of the body and respectively connected to two of the major connectors, and each minor connector having
a locating segment mounted in a corresponding mounting hole of the body and having a bottom, a top, a middle and an external surface;
a mounting stud formed on and protruding from the top of the locating segment at the middle of the locating segment, abutting the internal surface of a corresponding major connector and having
an external surface; and
a pressing wall formed on the external surface of the mounting stud and facing and abutting the abutting wall of the corresponding major connector; and
an assembling hole transversally formed through the mounting stud between the pressing wall and the locating segment and aligning with the mounting hole of the corresponding major connector; and
two fixing elements respectively mounted through the assembling holes of the minor connectors and securely mounted in the mounting holes of the corresponding major connectors to connect the longitudinal column securely with the corresponding major connectors.

2. The combined frame as claimed in claim 1, wherein
each side cover has a positioning bar formed on and protruding from the outer side of the side cover; and
each major connector has two positioning slots respectively formed in the side faces of the external surface of the major connector and mounted on the positioning bars of two adjacent transversal beams.

3. The combined frame as claimed in claim 2, wherein
each major connector has a positioning arm formed on and protruding from the bottom of the major connector along the internal surface of the major connector below the through holes of the corresponding major connector;
the locating segment of each minor connector has a locating recess formed in the external surface of the locating segment at the bottom of the locating segment and mounted on the positioning arm of a corresponding major connector; and
the positioning slots of each major connector are respectively formed in the side faces of the external surface of the major connector from the top to the positioning arm of the major connector.

4. The combined frame as claimed in claim 3, wherein
each major connector has a positioning recess formed in the abutting wall between the mounting hole and the top of the major connector; and
each minor connector has a locating protrusion formed on and protruding from the pressing wall of the mounting stud above the assembling hole and mounted in the positioning recess of a corresponding major connector.

5. The combined frame as claimed in claim 4, wherein
the positioning arm of each one of the major connector has an inner face and a mounting slot formed in the inner face of the positioning arm; and
each major connector has a waterproof bar mounted on and abutting the inner face of the positioning arm and engaging the mounting slot of the positioning arm.

6. The combined frame as claimed in claim 5, wherein
the positioning bar of each one of the side cover has an external surface and an engaging slot formed in the external surface of the positioning bar; and
each transversal beam has two waterproof bars respectively mounted on and abutting the external surfaces of the positioning bars of the side covers and respectively engaging the engaging slots of the positioning bars.

7. The combined frame as claimed in claim 1, wherein
each major connector has a positioning arm formed on and protruding from the bottom of the major connector along the internal surface of the major connector below the through holes of the corresponding major connector; and
the locating segment of each minor connector has a locating recess formed in the external surface of the locating segment at the bottom of the locating segment and mounted on the positioning arm of a corresponding major connector.

8. The combined frame as claimed in claim 7, wherein
each major connector has a positioning recess formed in the abutting wall between the mounting hole and the top of the major connector; and
each minor connector has a locating protrusion formed on and protruding from the pressing wall of the mounting stud above the assembling hole and mounted in the positioning recess of a corresponding major connector.

9. The combined frame as claimed in claim 8, wherein
the positioning arm of each one of the major connector has an inner face and a mounting slot formed in the inner face of the positioning arm; and
each major connector has a waterproof bar mounted on and abutting the inner face of the positioning arm and engaging the mounting slot of the positioning arm.

10. The combined frame as claimed in claim 9, wherein
the positioning bar of each one of the side cover has an external surface and an engaging slot formed in the external surface of the positioning bar; and
each transversal beam has two waterproof bars respectively mounted on and abutting the external surfaces of the positioning bars of the side covers and respectively engaging the engaging slots of the positioning bars.

11. The combined frame as claimed in claim 6, wherein the combined frame has
multiple supporting beams connected between two adjacent longitudinal columns and two of the transversal beams; and
multiple assembling blocks connected between two adjacent supporting beams, and each assembling block having
a block body securely connected to one of the two adjacent supporting beams and having two sidewalls, a front side and a rear side;
two holding wings respectively formed with the sidewalls of the block body and abutting the supporting beam that is securely connected to the block body;
a limiting panel formed on and protruding from the front side of the block body and abutting with the other one of the two adjacent supporting beams; and
a fastening board formed on and protruding from the rear side of the block body and securely connected to the supporting beam that abuts with the limiting panel.

12. The combined frame as claimed in claim 10, wherein the combined frame has
multiple supporting beams connected between two adjacent longitudinal columns and two of the transversal beams; and
multiple assembling blocks connected between two adjacent supporting beams, and each assembling block having
a block body securely connected to one of the two adjacent supporting beams and having two sidewalls, a front side and a rear side;
two holding wings respectively formed with the sidewalls of the block body and abutting the supporting beam that is securely connected to the block body;
a limiting panel formed on and protruding from the front side of the block body and abutting with the other one of the two adjacent supporting beams; and
a fastening board formed on and protruding from the rear side of the block body and securely connected to the supporting beam that abuts with the limiting panel.

13. The combined frame as claimed in claim 11, wherein each longitudinal column has multiple linking sets mounted on the body of the corresponding longitudinal column at intervals, and each linking set has
at least one linking block detachably mounted on the body of the corresponding longitudinal column and each of the at least one linking block having a connecting tab formed on and protruding from an outer side of the linking block; and
a connecting base mounted around the connecting tab of the at least one linking block.

14. The combined frame as claimed in claim 12, wherein each longitudinal column has multiple linking sets mounted on the body of the corresponding longitudinal column at intervals, and each linking set has
at least one linking block detachably mounted on the body of the corresponding longitudinal column and each of the at least one linking block having a connecting tab formed on and protruding from an outer side of the linking block; and
a connecting base mounted around the connecting tab of the at least one linking block.
